(19) United States
(12) Patent Application Publication
(10) Pub. No.: US 2009/0085678 A1
(43) Pub. Date: Apr. 2, 2009

(54) METHOD AND SYSTEM FOR SIGNAL GENERATION VIA A DIGITALLY CONTROLLED OSCILLATOR

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 11/864,839

(22) Filed: Sep. 28, 2007

(51) Int. Cl. H03L 7/099; H03L 7/08

(52) U.S. Cl. 331/1 A

(57) ABSTRACT

Aspects of a method and system for digitally controlling a VCO are provided. In this regard, a phase difference between two signals may be determined, represented digitally, and utilized to adjust the output frequency of a LOGEN. In this regard, the output frequency may be adjusted by controlling one or more switching elements coupled to one or more reactances, which may comprise a plurality of capacitors coupled in parallel, within the LOGEN. The phase difference may be determined by digitally multiplying the two signals, and the resulting product may be delta-sigma modulated. The two signals may be generated via one or more accumulators, which may be controlled, at least in part, by a digital control word. The control word may be retrieved from a look-up table. The accumulators may be clocked by a frequency divided version of the LOGEN output.

### CROSS-REFERENCE TO RELATED APPLICATIONS/INCORPORATION BY REFERENCE

Not Applicable

### FIELD OF THE INVENTION

Certain embodiments of the invention relate to signal processing. More specifically, certain embodiments of the invention relate to a method and system for signal generation via a digitally controlled oscillator

### BACKGROUND OF THE INVENTION

As frequencies utilized by various wireless technologies and devices continue to increase, signal generation for the processing, transmission, and/or reception of such signals is becoming increasingly challenging for wireless systems designers. In this regard, conventional methods of signal generation, such as integer-N and Fractional-N phase locked loops may be difficult or costly to implement as frequencies increase. For example, traditional signal generation circuits may require complicated and/or expensive tuning. Additionally, traditional signal generation circuits may require large amounts of circuit area. Accordingly, improved methods and systems for generating signals for the processing, transmission, and/or reception of signals up to extremely high frequencies are needed.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for signal generation via a digitally controlled oscillator, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary PLL with a digitally controlled oscillator, in accordance with an embodiment of the invention.

FIG. 2 is a flow chart illustrating exemplary steps for generating a signal via a PLL controlled with digital phase detection, in accordance with an embodiment of the invention.

FIG. 3a is a diagram of an exemplary digitally controlled oscillator, in accordance with an embodiment of the invention.

FIG. 3b is a diagram of an exemplary digitally controlled oscillator, in accordance with an embodiment of the invention.

FIG. 3c is a diagram of an exemplary digitally controlled oscillator, in accordance with an embodiment of the invention.

FIG. 4 is a diagram of a transceiver comprising a local oscillator generator (LOGEN) which may comprise a digitally controlled oscillator, in accordance with an embodiment of the invention.

FIG. 5 is a block diagram illustrating an exemplary RF communication device, in accordance with an embodiment of the invention.

### DETAILED DESCRIPTION OF THE INVENTION

Certain embodiments of the invention may be found in a method and system for digitally controlling a VCO. In this regard, a phase difference between two signals may be determined, represented digitally, and utilized to adjust the output frequency of a LOGEN. In this regard, the output frequency may be adjusted by controlling one or more switching elements coupled to one or more reactances, which may comprise a plurality of capacitors coupled in parallel, within the LOGEN. The phase difference may be determined by digitally multiplying the two signals, and the resulting product may be delta-sigma modulated. The two signals may be generated via one or more accumulators, which may be controlled, at least in part, by a digital control word. The control word may be retrieved from a look-up table. The accumulators may be clocked by a frequency divided version of the LOGEN output.

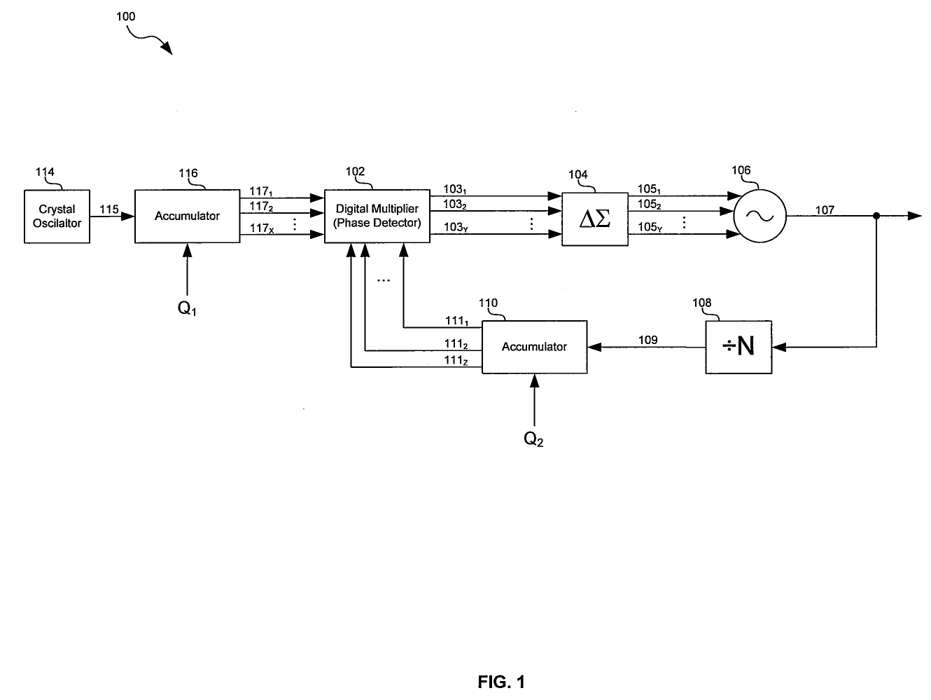

FIG. 1 is a block diagram illustrating an exemplary PLL with a digitally controlled oscillator, in accordance with an embodiment of the invention. Referring to FIG. 1 an exemplary PLL may comprise a crystal oscillator 114, an analog-to-digital converter (A/D) 116, a digital multiplier 102, a delta-sigma modulator 104, a digitally controlled oscillator 106, a frequency divider 108, and an accumulator 110.

The crystal oscillator 114 may comprise suitable logic, circuitry, and/or code that may enable generating a stable reference frequency.

The accumulator 116 may comprise suitable logic, circuitry, and/or code that may enable successively adding a control word Q1 to a value stored in the accumulator on each cycle of a reference clock. The accumulator 116 may receive the control word Q₁ and a reference signal. In this regard, the control word Q₁ and the reference signal may determine a phase and/or a frequency of the output signal 117. In an exemplary embodiment of the invention, the accumulator 116 may be clocked by the crystal oscillator 114. The control word Q₁ may be successively added to a value stored in the accumulator 116 on each cycle of the signal 115. In this manner, the sum may eventually be greater than the maximum value the accumulator may store, and the value in the accumulator may overflow or “wrap”. Accordingly, an n-bit accumulator may overflow at a frequency fₒ given by EQ. 1.

fₒ=f₁₁₅(Q₁/2ⁿ) EQ. 1

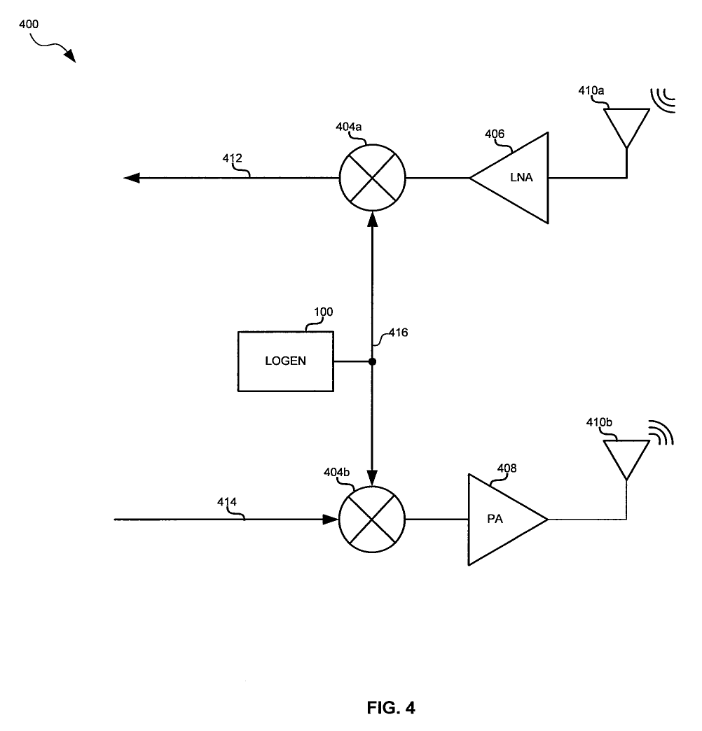

In this manner, the output of the accumulator, θ, may be periodic with period 1/fₒ. Additionally, the control word, Q₁, may be provided by, for example, the processor 425 of FIG. 4. In this regard, possible values of the control word may be generated based on possible values of the reference frequency 115 and the desired frequency of the signal 107. Values of the control word Q₂ may be stored in, for example, a look up table in the memory 427 of FIG. 4.

The digital multiplier 102 may comprise suitable logic, circuitry, and/or code that may enable multiplying the digital signals 111 and 117 and outputting the product via 103₁, . . . , 103_{y}. An average value of the signal 103 may be utilized to determine a phase difference between the signals 111 and 117. In this regard, an average value of 0 may indicate the signals 111 and 117 are in-phase, while a non-zero average value of the signal 103 may indicate a phase difference between the signals 111 and 117.

The delta-sigma modulator 104 may comprise suitable logic, circuitry, and/or code that may enable oversampling the signal 103 and shaping the quantization noise to generate the signal 105. In various embodiments of the invention, the signal 105 output by the delta-sigma modulator may comprise one or more bits, which may be conveyed serially or in parallel.

The digitally controlled oscillator 106 may comprise suitable logic, circuitry, and/or code that may enable generating a signal 107 based on a digital control signal 105. In this regard, the frequency of the signal 107 may be determined, at least in part, by the signal 105.

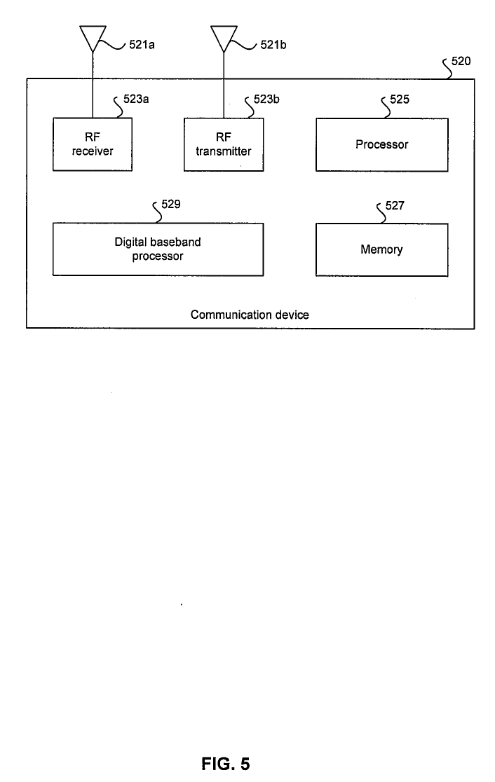

The frequency divider 108 may comprise suitable logic, circuitry, and/or code for receiving a first, higher frequency and outputting a second, lower frequency. The scaling factor, N, may be determined based on one or more control signals from, for example, the processor 525 of FIG. 5. In this regard, values for the frequency divider may be stored in, for example, a look-up table in the memory 527 of FIG. 5.

The accumulator 110 may comprise suitable logic, circuitry, and/or code that may enable successively adding a digital control word Q₂ to a value stored in the accumulator on each cycle of a reference clock. The accumulator may receive the control word Q₂ and a reference signal. In this regard, the control word Q₂ and the reference signal may determine a phase and/or a frequency of the output signal 111. In an exemplary embodiment of the invention, the accumulator may be clocked by the VCO output 107, or, as depicted in FIG. 1, the signal 109 which may be a divided down version of the VCO output 107. The control word Q may be successively added to a value stored in the accumulator on each cycle of the reference clock. In this manner, the sum may eventually be greater than the maximum value the accumulator 110 may store, and the value in the accumulator may overflow or “wrap”. Accordingly, an N-bit accumulator will overflow at a frequency fₒ given by EQ. 2.

fₒ=f₁₀₉(Q₂/2ⁿ) EQ. 2

In this manner, the output of the accumulator, θ, may be periodic with period 1/fₒ. Additionally, the control word, Q₂, may be provided by, for example, the processor 525 of FIG. 5. In this regard, possible values of the control word may be stored in, for example, a look up table in the memory 527 of FIG. 5.

In operation the LOGEN 100 may generate a signal 107 based on the fixed frequency reference signal 115 from the crystal oscillator 114. In this regard, the accumulator 110 may enable generating, based on the signal 109 and the control word Q, a digital signal 111. The signal 111 may provide feedback such that the oscillator 106 may generate a signal of varying frequency while having the stability of the fixed frequency crystal oscillator 114. In this regard, the multiplier 102 may compare the phase of the signal 117 to the phase of the signal 111 and generate an error signal 103 indicative of the phase difference between the signals 111 and 117. The error signal 103 may be a digital signal comprising one or more bits. In various embodiments of the invention, the error signal 103 may be delta-sigma modulated for noise shaping. The error signal 103, or the delta-sigma modulated signal 105, may control one or more switching elements comprising the digitally controlled oscillator 106. By configuring the switching elements, the output frequency of the oscillator 106 may be adjusted. In this manner, the phase error between the signal 111 and the signal 117 may be maintained within determined limits. Accordingly, the output signal 107 of the oscillator 106 may be any integer multiple or fractional multiple of the reference signal 115. In this regard, the signal 111 may be determined using

$${f}_{111} = \frac{{f}_{107}}{N} \cdot {Q}_{2} \cdot \frac{1}{{2}^{n}} \qquad EQ . 3$$

where f₁₁₁ is the frequency of the signal 111, f₁₀₇ is the frequency of the signal 107, N is the divide ratio of the frequency divider 108, Q is the value of the control word input to the accumulator 110, and ‘n’ is the number of bits of the accumulator. Accordingly, the LOGEN 100 may be enabled to generate a wide range of frequencies, with high resolution, without the need of a traditional fractional-N synthesizer.

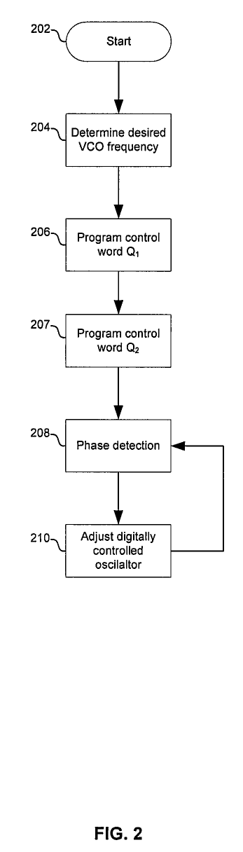

FIG. 2 is a flow chart illustrating exemplary steps for generating a signal via a PLL controlled with digital phase detection, in accordance with an embodiment of the invention. Referring to FIG. 2, the exemplary steps may begin with start step 202. Subsequent to start step 202, the exemplary steps may advance to step 204. In step 204, a desired frequency to be output by the digitally controlled oscillator 106 may be determined. In this regard, if the LOGEN 100 is being utilized to transmit or receive RF signals, then the output of the digitally controlled oscillator 106 may be determined based on the RF transmit and/or RF receive frequency. Subsequent to step 204, the exemplary steps may advance to step 206. In step 206, the digital control word Q₁ input to the accumulator 116 may be determined. In this regard, the value of the digital control word Q₁ may be determined based on a desired reference frequency of the signal 117. Subsequent to step 206, the exemplary steps may advance to step 207. In step 207, the digital control word Q₂ input to the accumulator 110 may be determined. In this regard, the value of the digital control word Q₂ may be determined utilizing EQ. 3 above. Accordingly, for different values of the reference frequency 115 and/or the desired output frequency 107, the value of the digital output word may be adjusted. In this regard, a processor, such as the processor 525 or the processor 529 of FIG. 5, may programmatically control the value of the digital control word.

Subsequent to step 206, the exemplary steps may advance to step 208. In step 208, a phase difference between the signal 111 and the signal 117 may be determined. The phase difference may be determined by multiplying the signals 111 and 117. In this regard, the average value of the product of the signals 111 and 117 may be indicative of a phase difference between the signals 111 and 117. Subsequent to step 208, the exemplary steps may advance to step 210. In step 210, the digitally controlled oscillator 106 may be adjusted based on the phase difference between the signals 111 and 117. For example, a capacitance coupled to an output node of the digitally controlled oscillator 106 may be adjusted via one or more switching elements such that the phase difference between the signals 111 and 117 may be reduced. Accordingly, when there may be no phase difference between the signals 111 and 117 the PLL may be said to be “locked”. Subsequent to step 210, the exemplary steps may return to step 208. In this regard, maintaining phase lock may be a continuous process that requires periodic or even constant feedback.

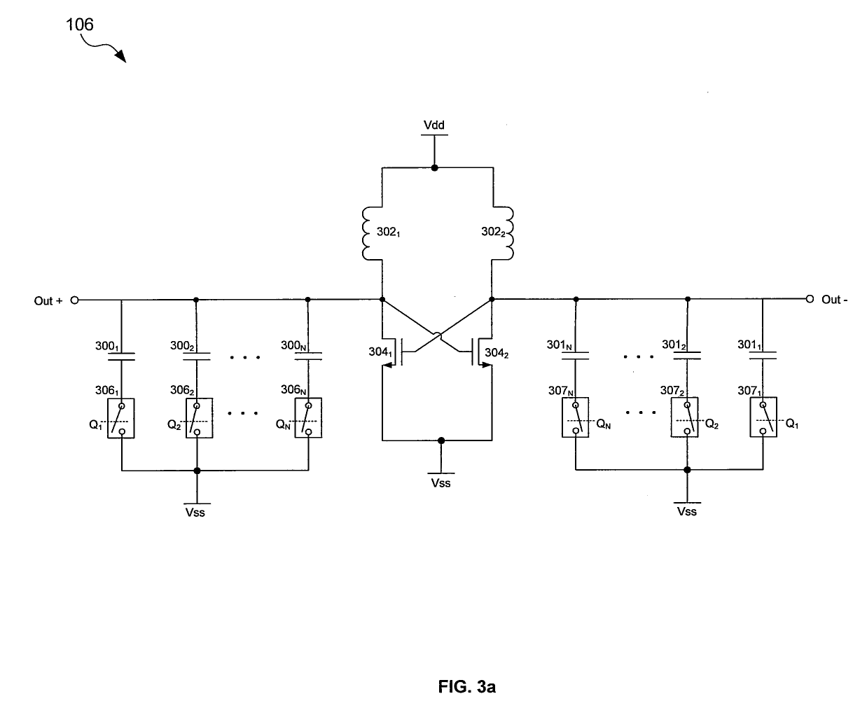

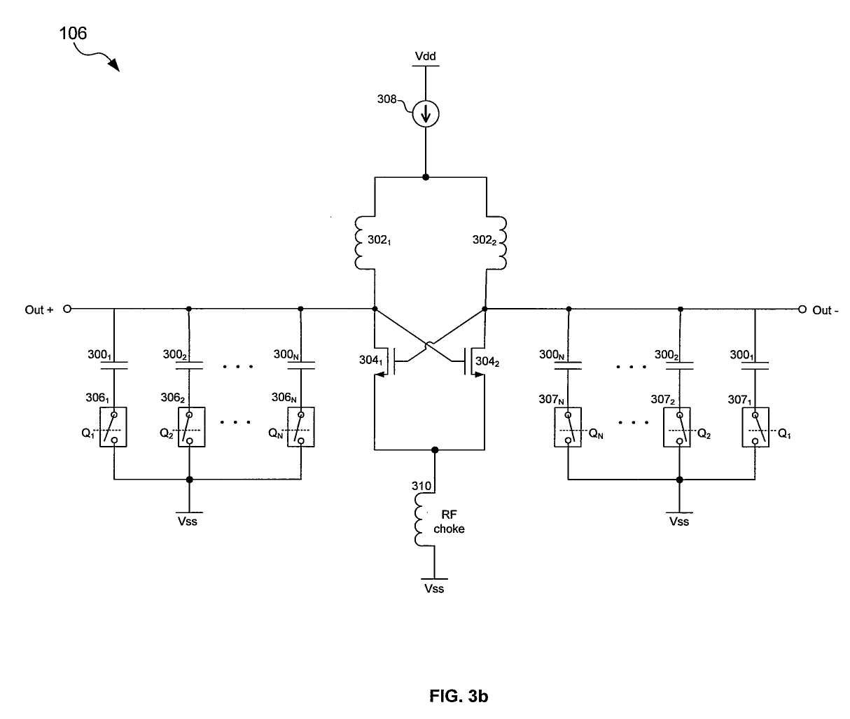

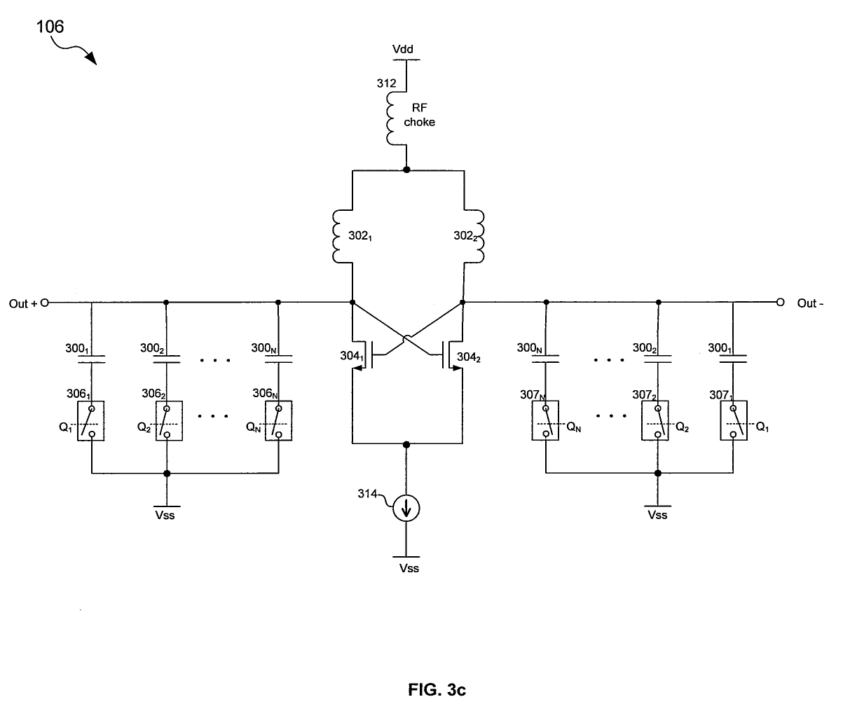

FIG. 3a is a diagram of an exemplary digitally controlled oscillator, in accordance with an embodiment of the invention. Referring to FIG. 3a there is shown an exemplary digitally controlled oscillator 106 which may comprise one or more capacitors 300 and 301, one or more switching elements 306 and 307, a pair of transistors 304, and a pair of inductors 302.

In operation, the switching elements may be controlled by one or digital signals. In this regard, the switches may enable coupling and decoupling the capacitors 300 and 301 to the output nodes “out +” and/or “out −”. Accordingly, depending on the value of the digital signal(s) Q₁, . . . , Q_{N}, one or more capacitances 300, 301 may be coupled or decoupled from the output nodes and thus alter the frequency of oscillation of the outputs. In this regard, when the delta-sigma modulator 104 is present, the signal 105 may switch rapidly, and the effective capacitance coupled to the output nodes of the oscillator 106 may depend on factors such as the switching frequency and duty cycle of the signal 105.

FIG. 3b is a diagram of an exemplary digitally controlled oscillator, in accordance with an embodiment of the invention. In this regard, FIG. 3b depicts an alternative to the embodiment illustrated in FIG. 3a. Referring to FIG. 3b there is shown an exemplary digitally controlled oscillator 106 which may comprise one or more capacitors 300 and 301, one or more switching elements 306 and 307, a pair of transistors 304, a pair of inductors 302, a current source 308, and an RF choke 310.

The capacitors 300 and 301, switching elements 306 and 307, transistors 304, and inductors 302 may be as described in FIG. 3a. The current source 308 may comprise suitable logic, circuitry, and/or code for supplying a constant (within determined limits) current. The RF choke 310 may enable sinking DC current to GND while impeding AC current. The digitally controlled oscillator of FIG. 3b may enable alternative biasing arrangements as compared to the digitally controlled oscillator of FIG. 3a. Accordingly, choosing one embodiment or the other may provide flexibilty when designing a the LOGEN 100.

FIG. 3c is a diagram of an exemplary digitally controlled oscillator, in accordance with an embodiment of the invention. In this regard, FIG. 3c depicts an alternative to the embodiments illustrated in FIG. 3a and 4b. Referring to FIG. 3b there is shown an exemplary digitally controlled oscillator 106 which may comprise one or more capacitors 300 and 301, one or more switching elements 306 and 307, a pair of transistors 304, a pair of inductors 302, a current source 308, and an RF choke 310.

The capacitors 300 and 301, switching elements 306 and 307, transistors 304, and inductors 302 may be as described in FIG. 3a. The RF choke 312 may enable passing DC current from VDD while impeding AC current. The current source 314 may comprise suitable logic, circuitry, and/or code for sinking a constant (within determined limits) current. The digitally controlled oscillator of FIG. 3c may enable alternative biasing arrangements as compared to the digitally controlled oscillators of FIG. 3a and FIG. 3b. Accordingly, choosing between the various embodiments may provide flexibilty when designing the LOGEN 100.

FIG. 4 is a diagram of a transceiver comprising a local oscillator generator (LOGEN) which may comprise a digitally controlled oscillator, in accordance with an embodiment of the invention. Referring to FIG. 4 there is shown a transceiver 400 which may be all or a portion of the RF receiver 523a of FIG. 5, for example. The transceiver 400 may comprise local oscillator generator (LOGEN) 100, mixers 404a and 404b, a low noise amplifier (LNA) 406, a power amplifier 408, and antennas 410a and 410b.

The LOGEN 100 may comprise suitable logic, circuitry, and/or code that may enable generating a reference signal. In this regard, the LOGEN 100 may comprise a phase locked loop (PLL) which may have a digitally controlled oscillator. In this regard, the LOGEN 100 may be as described with respect to FIG. 1. Accordingly, the signal 116 may be the same as the signal 107 in FIG. 1. In an exemplary embodiment of the invention, the transceiver 400 may directly convert between RF and baseband. Accordingly, the frequency of the signal 416, F_{LO}, may be (F_{RF}±F_{baseband}).

The mixer 404a may comprise suitable logic, circuitry, and/or code that may enable generation of inter-modulation products resulting from mixing the output of the LNA 406 and the LO signal 416. Similarly, the mixer 404b may comprise suitable logic, circuitry, and/or code that may enable generation of inter-modulation products resulting from mixing the baseband signal 414 and the LO signal 416. In various embodiments of the invention the output of the mixers 404a and 404b may be filtered such that desired inter-modulation products are passed with less attenuation than undesired inter-modulation products.

The LNA 406 may comprise suitable logic, circuitry, and/or code that may enable buffering and/or amplification of received RF signals. In this regard, the gain of the LNA 406 may be adjustable to enable reception of signals of varying strength. Accordingly, the LNA 406 may receive one or more control signals from a processor such as the processors 525 and 529 of FIG. 5.

The PA 408 may comprise suitable logic, circuitry, and/or code that may enable buffering and/or amplification of a RF signal and outputting the signal to an antenna for transmission. In this regard, the gain of the PA 408 may be adjustable and may enable transmitting signals of varying strength. Accordingly, the PA 408 may receive one or more control signals from a processor such as the processors 525 and 529 of FIG. 5.

The antennas 410a and 410b may comprise suitable logic, circuitry, and/or code that may enable reception and/or transmission of signals. In various embodiments of the invention there may be separate transmit and receive antennas, as depicted, or there may be a single antenna for both transmit and receive functions.

In an exemplary receive operation, RF signals may be received by the antenna 410a and may be conveyed to the LNA 406. The LNA 406 may amplify the received signal and convey it to the mixer 404a. In this regard, the gain of the LNA 406 may be adjusted based on received signal strength. Additionally, the gain may be controlled via one or more control signals from, for example, a processor such as the processors 525 and 529. The LO signal 416 may be coupled to the mixer 404a such that the received signal of frequency F_{RF} may be down-converted to a baseband signal 412. In this regard, a frequency of the signal 416 may be determined based on a frequency of the received RF signal and may be controlled, at least in part, via the digital control words Q₁ and Q₂ of FIG. 1. The baseband signal 412 may be conveyed, for example, to a baseband processor such as the baseband processor 529.

In an exemplary transmit operation, a baseband signal 414 may be conveyed to the mixer 404b. The LO signal 416 may be coupled to the mixer 404b and the baseband signal 414, of frequency F_{baseband,} may be up-converted to RF. In this regard, a frequency of the signal 416 may be determined based on a desired transmit frequency and may be controlled, at least in part, via the digital control words Q₁ and Q₂ of FIG. 1 The RF signal may be conveyed to the PA 408 for transmission via the antenna 410b. In this regard, the gain of the PA 408 may be adjusted via one or more control signals from, for example, a processor such as the processors 525 and 529 of FIG. 5.

FIG. 5 is a block diagram illustrating an exemplary RF communication device, in accordance with an embodiment of the invention. Referring to FIG. 5, there is shown a RF communication device 520 that may comprise an RF receiver 523a, an RF transmitter 523b, a digital baseband processor 529, a processor 525, and a memory 527. A receive antenna 521a may be communicatively coupled to the RF receiver 523a. A transmit antenna 521b may be communicatively coupled to the RF transmitter 523b. The RF communication device 520 may be operated in a system, such as the cellular network and/or digital video broadcast network, for example.

The RF receiver 523a may comprise suitable logic, circuitry, and/or code that may enable processing of received RF signals. In this regard, the receiver may be enabled to generate signals, such as local oscillator signals, for the reception and processing of RF signals. The RF receiver 523a may down-convert received RF signals to a baseband frequency signal. The RF receiver 523a may perform direct down-conversion of the received RF signal to a baseband frequency signal, for example. In some instances, the RF receiver 523a may enable analog-to-digital conversion of the baseband signal components before transferring the components to the digital baseband processor 529. In other instances, the RF receiver 523a may transfer the baseband signal components in analog form.

The digital baseband processor 529 may comprise suitable logic, circuitry, and/or code that may enable processing and/or handling of baseband frequency signals. In this regard, the digital baseband processor 529 may process or handle signals received from the RF receiver 523a and/or signals to be transferred to the RF transmitter 523b. The digital baseband processor 529 may also provide control and/or feedback information to the RF receiver 523a and to the RF transmitter 523b based on information from the processed signals. In this regard, the baseband processor 529 may provide one or more control signals to, for example, the accumulator 114, the multiplier 102, the delta-sigma modulator 104, the oscillator 106, the frequency divider 108, and/or the accumulator 110. The digital baseband processor 529 may communicate information and/or data from the processed signals to the processor 525 and/or to the memory 527. Moreover, the digital baseband processor 529 may receive information from the processor 525 and/or to the memory 527, which may be processed and transferred to the RF transmitter 523b for transmission to the network.

The RF transmitter 523b may comprise suitable logic, circuitry, and/or code that may enable processing of RF signals for transmission. In this regard, the transmitter may be enabled to generate signals, such as local oscillator signals, for the transmission and processing of RF signals. The RF transmitter 523b may up-convert the baseband frequency signal to an RF signal. The RF transmitter 523b may perform direct up-conversion of the baseband frequency signal to a RF signal, for example. In some instances, the RF transmitter 523b may enable digital-to-analog conversion of the baseband signal components received from the digital baseband processor 529 before up conversion. In other instances, the RF transmitter 523b may receive baseband signal components in analog form.

The processor 525 may comprise suitable logic, circuitry, and/or code that may enable control and/or data processing operations for the RF communication device 520. The processor 525 may be utilized to control at least a portion of the RF receiver 523a, the RF transmitter 523b, the digital baseband processor 529, and/or the memory 527. In this regard, the processor 525 may generate at least one signal for controlling operations within the RF communication device 520. In this regard, the baseband processor 529 may provide one or more control signals to, for example, the accumulator 114, the multiplier 102, the delta-sigma modulator 104, the oscillator 106, the frequency divider 108, and/or the accumulator 110. The processor 525 may also enable executing of applications that may be utilized by the RF communication device 520. For example, the processor 525 may execute applications that may enable displaying and/or interacting with content received via RF signals in the RF communication device 520.

The memory 527 may comprise suitable logic, circuitry, and/or code that may enable storage of data and/or other information utilized by the RF communication device 520. For example, the memory 527 may be utilized for storing processed data generated by the digital baseband processor 529 and/or the processor 525. The memory 527 may also be utilized to store information, such as configuration information, that may be utilized to control the operation of at least one block in the RF communication device 520. For example, the memory 527 may comprise information necessary to configure the RF receiver 523a to enable receiving signals in the appropriate frequency band. In this regard, the memory 527 may store configuration and/or control information for the accumulator 114, the multiplier 102, the delta-sigma modulator 104, the oscillator 106, the frequency divider 108, and/or the accumulator 110.

Aspects of a method and system for digitally controlling a VCO are provided. In this regard, a phase difference between two signals 117 and 111 may be determined, represented digitally, and utilized to adjust the output frequency of a LOGEN 100. In this regard, the output frequency may be adjusted by controlling one or more switching elements 307 coupled to one or more reactances, which may comprise a plurality of capacitors 301 coupled in parallel, within the LOGEN 100. The phase difference may be determined by digitally multiplying the two signals 111 and 117, and the resulting product may be delta-sigma modulated. The two signals may be generated by accumulators 116 and 110, which may be controlled, at least in part, by digital control words Q₁ and Q₂. The control word may be retrieved from a look-up table. The accumulators may be clocked by a frequency divided version of the LOGEN 100 output.

Another embodiment of the invention may provide a machine-readable storage, having stored thereon, a computer program having at least one code section executable by a machine, thereby causing the machine to perform the steps as described herein for digitally controlling a VCO are provided.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal generation, the method comprising:
in a local oscillator generator:
determining a phase difference between two signals;
generating a digital representation of said determined phase difference; and
adjusting a frequency of an output signal of said local oscillator generator by utilizing said generated digital representation of said determined phase difference to control one or more switching elements coupled to one or more reactances within said local oscillator generator.

2. The method according to claim 1, comprising determining said phase difference via a digital multiplication of said two signals.

3. The method according to claim 1, comprising delta-sigma modulating said digital representation of said phase difference.

4. The method according to claim 1, comprising generating at least one of said two signals via at least one accumulator clocked by said output signal of said local oscillator generator.

5. The method according to claim 4, comprising programmatically controlling a digital control word input to each of said at least one accumulator.

6. The method according to claim 4, comprising frequency dividing said output of said local oscillator generator prior to said clocking.

7. The method according to claim 1, comprising acquiring said digital control word from a lookup table (LUT) based on said output of said local oscillator generator and based on said reference signal

8. The method according to claim 1, wherein said reactances comprise one or more capacitances coupled in parallel via said switching elements.

9. A machine-readable storage having stored thereon, a computer program having at least one code section for signal generation, the at least one code section being executable by a machine for causing the machine to perform steps comprising:
In a local oscillator generator:
determining a phase difference between two signals;
generating a digital representation of said determined phase difference; and
adjusting a frequency of an output signal of said local oscillator generator by utilizing said generated digital representation of said determined phase difference to control one or more switching elements coupled to one or more reactances within said local oscillator generator.

10. The machine-readable storage according to claim 9, wherein said at least one code section enables determining said phase difference via a digital multiplication of said two signals.

11. The machine-readable storage according to claim 9, wherein said at least one code section enables delta-sigma modulating said digital representation of said phase difference.

12. The machine-readable storage according to claim 9, wherein said at least one code section enables generating at least one of said two signals via at least one accumulator clocked by said output signal of said local oscillator generator.

13. The machine-readable storage according to claim 12, wherein said at least one code section enables programmatically controlling a digital control word input to each of said at least one accumulator.

14. The machine-readable storage according to claim 12, wherein said at least one code section enables frequency dividing said output of said local oscillator generator prior to said clocking.

15. The machine-readable storage according to claim 9, wherein said at least one code section enables acquiring said digital control word from a lookup table (LUT) based on said output of said local oscillator generator and based on said reference signal

16. The machine-readable storage according to claim 9, wherein said reactances comprise one or more capacitances coupled in parallel via said switching elements.

17. A system for signal generation, the system comprising:
one or more circuits of a local oscillator generator that, at least:
determine a phase difference between two signals;
generate a digital representation of said determined phase difference; and
adjust a frequency of an output signal of said local oscillator generator by utilizing said generated digital representation of said determined phase difference to control one or more switching elements coupled to one or more reactances within said local oscillator generator.

18. The system according to claim 17, wherein said one or more circuits determine said phase difference via a digital multiplication of said two signals.

19. The system according to claim 17, wherein said one or more circuits delta-sigma modulate said digital representation of said phase difference.

20. The system according to claim 17, wherein said one or more circuits generate at least one of said two signals via at least one accumulator clocked by said output signal of said local oscillator generator.

21. The system according to claim 20, wherein said one or more circuits programmatically control a digital control word input to each of said at least one accumulator.

22. The system according to claim 20, wherein said one or more circuits frequency divide said output of said local oscillator generator prior to said clocking.

23. The system according to claim 17, wherein said one or more circuits acquire said digital control word from a lookup table (LUT) based on said output of said local oscillator generator and based on said reference signal 24. The system according to claim 17, wherein said reactances comprise one or more capacitances coupled in parallel via said switching elements.
